(19) United States
(12) Patent Application Publication
(10) Pub. No.: US 2025/0143116 A1
(43) Pub. Date: May 1, 2025

(54) Display Device

(71) Applicant: LG Display Co., Ltd., Seoul (KR)

(72) Inventor: Jooho Lee, Paju-si (KR)

(21) Appl. No.: 18/767,871

(22) Filed: Jul. 9, 2024

(30) Foreign Application Priority Data
Oct. 30, 2023 (KR) 10-2023-0146456

(51) Int. Cl. H10K 59/131; H10K 59/124

(52) U.S. Cl. CPC H10K 59/131; H10K 59/124

(57) ABSTRACT

A display device includes: a display panel including an active area and a non-active area; and a driving chip disposed in the non-active area. The display panel includes a crack prevention pattern which is disposed such that at least a portion of the crack prevention pattern overlaps an edge of one short side of the driving chip. As a result, moisture penetration and metal corrosion are prevented or at least reduced, so that the reliability of the display device can be improved and the deformation of the display panel can be minimized or at least reduced.

### CROSS-REFERENCE TO RELATED APPLICATION

The present application claims the benefit of Republic of Korea Patent Application No. 10-2023-0146456, filed Oct. 30, 2023, which is incorporated herein by reference in its entirety.

### FIELD

The present disclosure relates to a display device and more particularly to a display device capable of improving reliability.

### BACKGROUND

A display device that displays images or videos on TVs, monitors, smartphones, tablet personal computers (PCs), laptops, etc., is used in various types and forms.

The display device includes a plurality of light emitting devices or liquid crystal, and a display panel including a transistor for controlling the operation of each light emitting device or liquid crystal. The display device displays images or videos to be displayed as they are through the plurality of light emitting devices or liquid crystal.

An organic light emitting display device including a self-light emitting device can be thinner than a display device with a built-in light source and requires no separate light source. Therefore, it is possible to produce a display device that can be bent or has various designs.

With the development of the information society, the field of the display device that displays electric information signals visually is rapidly growing. Also, researches are being devoted to the performance improvement of various display devices, such as being thinner, consuming lower power, and obtaining reliability, etc.

### SUMMARY

The purpose of the embodiment of the present disclosure is to provide a display device which enhances reliability by preventing moisture permeation caused by the lifting of the insulation layer around the driving chip and by preventing the corrosion defect of the pad or wiring.

The purpose of the embodiment of the present disclosure is to provide a display device which prevents or at least reduces that stress is concentrated when the driving chip is mounted on the display panel, and cracks occur around the driving chip, thereby reducing the deformation of the display panel.

The purpose of the embodiment of the present disclosure is to provide a display device which is capable of reducing production energy for producing the display device by utilizing the same process and by minimizing or at least reducing the defect occurrence of the display device and is capable of reducing the use of hazardous production materials or regulated materials, so that the display device is advantageous for recycling and leads to the implementation of the eco-friendly display device.

One embodiment is a display device including: a display panel including an active area and a non-active area; and a driving chip disposed in the non-active area. The display panel includes a crack prevention pattern which is disposed such that at least a portion of the crack prevention pattern overlaps an edge of one short side of the driving chip.

The crack prevention pattern may be disposed in the non-active area in a direction parallel to the edge of one short side of the driving chip.

The crack prevention pattern may be arranged on both short sides of the driving chip to be parallel to the short side of the driving chip such that at least a portion of the crack prevention pattern overlaps edges of both short sides of the driving chip.

At least a portion of the crack prevention pattern may be arranged to overlap the edge of the driving chip.

The crack prevention pattern may be arranged to overlap four points of the edge of the driving chip.

The display panel may include: a substrate; a plurality of insulating layers which are stacked and disposed in the non-active area on the substrate; a planarization layer which is disposed on the crack prevention pattern on the plurality of insulating layers; and a first pad which is disposed to be spaced apart from the crack prevention pattern. The planarization layer may be disposed on the insulating layer exposed to a spaced space between the crack prevention pattern and the first pad and on a side of the first pad.

The edge of one short side of the driving chip may overlap the planarization layer and the crack prevention pattern.

The display device may further include an anisotropic conductive film disposed between the driving chip and the first pad. The anisotropic conductive film may overlap at least a portion of the planarization layer and the crack prevention pattern at the edge of one short side of the driving chip.

The crack prevention pattern may be formed in an embossed pattern including a metal layer.

The display device may further include: a first pad which is disposed toward the active area in the non-active area; and a second pad which is disposed in an opposite direction to the active area while facing the first pad. The first pad and the second pad may overlap both long sides of the driving chip, and the crack prevention pattern may be disposed to be spaced apart from the first pad and the second pad so as not to overlap the first pad and the second pad.

The crack prevention pattern may be made of the same material as that of the first pad or the second pad.

At least a portion of the crack prevention pattern may not overlap edges of both short sides of the driving chip, and a plurality of the crack prevention patterns may be arranged to be spaced apart from each other in such a manner as to overlap four points of the edge of the driving chip.

The crack prevention pattern according to embodiment of the present disclosure is arranged such that at least a portion of the crack prevention pattern overlaps the edge of the short side of the driving chip, so that it is possible to prevent or at least reduce that stress due to pressure, etc., is concentrated when mounting the driving chip and the stress is generated. Therefore, it is possible to prevent or at least reduce deformation of the display panel due to the stress or to prevent or at least reduce the occurrence of crack in the display panel due to the interference with the driving chip.

According to the display device according to the embodiment, the crack prevention pattern of the embodiment of the present disclosure is arranged to overlap the edge of the short side of the driving chip, thereby preventing cracks around the driving chip when the driving chip is bonded. As a result, it is possible to prevent or at least reduce moisture penetration due to the crack, the lifting of surrounding insulating layers due to the moisture penetration, and the occurrence of crack in the surrounding insulating layers due to the lifting.

Since the crack prevention pattern according to the embodiment of the present disclosure can prevent or at least reduce cracks from occurring in the insulating layers disposed around the driving chip, it is possible to prevent or at least reduce that the surrounding pads or wirings, etc., are corroded or cracked through the moisture penetration due to the cracks of the insulating layer. Also, the crack prevention pattern according to the present disclosure can prevent or at least reduce cracks and moisture penetration, thereby reducing the deformation of the display panel.

In the display device according to the present disclosure, the crack prevention pattern is arranged such that at least a portion of the crack prevention pattern overlaps the edge of the driving chip, thereby blocking moisture penetration and preventing the corrosion of the metal disposed in the non-active area of the display device. As a result, the reliability of the display device can be improved.

According to the display device according to the embodiment, when a metal layer is disposed as the crack prevention pattern, rigidity can be obtained, so that the crack prevention pattern can support against pressure-like pressing when mounting the driving chip, thereby preventing cracks from occurring around the driving chip. Therefore, the deformation of the display panel can be reduced with a more improved effect.

According to the display device according to the embodiment, the crack prevention pattern is disposed using the same process and the defect occurrence of the display device is minimized by the crack prevention pattern. Accordingly, the production energy for producing the display device can be reduced and the use of hazardous production materials or regulated materials can be reduced, so that the display device is advantageous for recycling and leads to the implementation of the eco-friendly display device.

### BRIEF DESCRIPTION OF THE DRAWINGS

FIG. 1 is a plan view of a display device according to an embodiment;

FIG. 2 is a circuit diagram of a sub-pixel according to the embodiment;

FIG. 3 is an enlarged fragmentary plan view of a part “A” of FIG. 1 according to an embodiment;

FIG. 4 is a partial plan view of a driving circuit area in the plan view of FIG. 1 according to the embodiment;

FIG. 5 is a partial plan view of a driving circuit area in the plan view of FIG. 1 according to another embodiment; and

FIG. 6 shows a cross-sectional view taken along line I-I′ of FIG. 1 according to an embodiment.

### DETAILED DESCRIPTION

Hereinafter, embodiments will be described with reference to the accompanying drawings.

The same reference numerals correspond to the same components. Also, in the drawings, the thicknesses, ratios, and dimensions of the components may be exaggerated for effective description of the technical details. Since the components shown in the drawings have scales different from actual scales thereof for convenience of description, the components are not limited to the scales shown in the drawings.

In this specification, when it is mentioned that a component (or region, layer, portion) “is on”, “is connected to”, or “is combined with” another component, terms “is on”, “connected to”, or “combined with” mean that a component may be directly connected to/combined with another component or mean that a third component may be disposed between them.

A term “and/or” includes all of one or more combinations that related configurations can define.

While terms such as the first and the second, etc., can be used to describe various components, the components are not limited by the terms mentioned above. The terms are used only for distinguishing between one component and other components. For example, the first component may be designated as the second component without departing from the scope of rights of various embodiments. Similarly, the second component may be designated as the first component. An expression of a singular form includes the expression of plural form thereof unless otherwise explicitly mentioned in the context.

Terms such as “below”, “lower”, “above”, “upper” and the like are used to describe the relationships between the components shown in the drawings. These terms have relative concepts and are described based on directions indicated in the drawings. One or more other parts may be positioned between the two parts as long as a term “directly” or “immediately” is not used. Spatially relative terms, such as “below, beneath”, “lower”, “above”, “upper”, etc., may be used for ease of description to describe correlations between one element or components and another element or components. The spatially relative terms must be understood as including different orientations of the device in use or operation in addition to the orientation depicted in the drawings. For example, when the element shown in the drawing is turned upside down, the element described as being “below” or “beneath” another element may be placed above said another element. Therefore, the exemplary term “below” may include both an up direction and a down direction.

In the present specification, it should be understood that the term “include” or “comprise” and the like is intended to specify characteristics, numbers, steps, operations, components, parts or any combination thereof, and intended not to previously exclude the possibility of existence or addition of at least one another characteristics, numbers, steps, operations, components, parts or any combination thereof.

The features of the various embodiments of the present disclosure can be partially or entirely coupled to or combined with each other, and the features can be technically and variously connected and driven. Also, the embodiments can be implemented independently of each other or together in an association relationship.

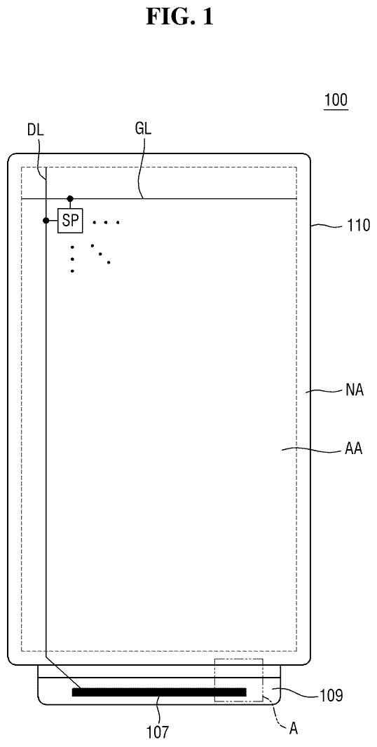

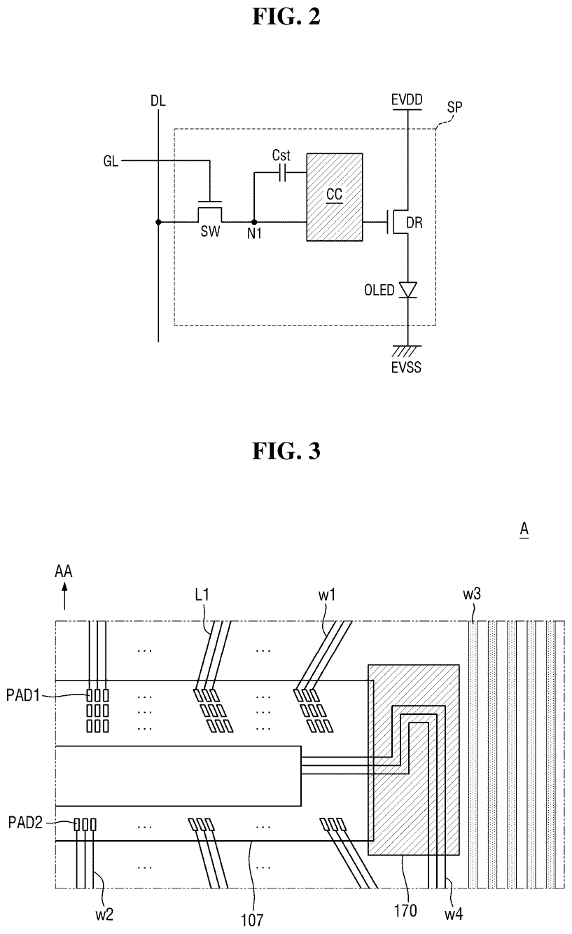

Hereinafter, a display device of the present disclosure will be described with reference to the accompanying drawings and embodiments. FIG. 1 is a plan view of a display device according to an embodiment. FIG. 2 is a circuit diagram of a sub-pixel according to the embodiment.

Referring to FIGS. 1 and 2, the display device 100 according to the embodiment of the present disclosure includes a display panel 110 including an active area AA and a non-active area NA, and a driving chip 107 disposed in the non-active area NA of the display panel 110. The driving chip 107 may be disposed in a driving circuit area 109 of the non-active area NA. The display panel 110 includes a crack prevention pattern 170 that is arranged to at least partially overlap the crack prevention pattern 170 in the driving circuit area 109.

The active area AA displays an image. A plurality of sub-pixels SP are disposed in the active area AA of the display panel 110, and an image can be displayed using the plurality of sub-pixels SP. The area where the plurality of sub-pixels SP are arranged may be the active area AA, and the area other than the active area AA may be the non-active area NA.

Referring to FIG. 2, at least one sub-pixel SP among the plurality of pixels include a switching transistor SW, a driving transistor DR, a capacitor Cst, a compensation circuit CC, and an organic light-emitting diode OLED.

A first electrode (e.g., drain electrode) of the switching transistor SW is electrically connected to a data line DL, and a second electrode (e.g., source electrode) of the switching transistor SW is electrically connected to a first node N1. A gate electrode of the switching transistor SW is electrically connected to a gate line GL. The switching transistor SW transmits a data signal supplied through the data line DL to the first node N1 in response to a scan signal supplied through the gate line GL.

The capacitor Cst is electrically connected to the first node N1 and is charged with a voltage applied to the first node N1.

A first electrode (e.g., drain electrode) of the driving transistor DR is applied with a high potential driving voltage EVDD, and a second electrode (e.g., source electrode) of the driving transistor DR is electrically connected to a first electrode (e.g., anode electrode) of the organic light-emitting diode OLED. The driving transistor DR may control the amount of driving current flowing through the organic light-emitting diode OLED in response to a voltage applied to a gate electrode of the driving transistor DR.

A semiconductor layer of the switching transistor SW or/and driving transistor DR may include silicon such as amorphous silicon (a-Si), polycrystalline silicon (poly-Si), or low-temperature polycrystalline silicon (poly-Si), etc., or may include oxides such as indium-gallium-zinc-oxide (IGZO), etc. However, the embodiment is not limited thereto.

The organic light-emitting diode OLED outputs light corresponding to the driving current. The organic light-emitting diode OLED may output light corresponding to any one of red, green, blue, and white.

The organic light-emitting diode OLED may include an anode electrode, a light emitting layer disposed on the anode electrode, and a cathode electrode that supplies a common voltage. The light emitting layer may be implemented to emit light of the same color for each pixel, such as white light, or to emit light of different colors for each sub-pixel SP, such as red, green, or blue light.

The organic light-emitting diode OLED may be a front emission type diode or a back emission type diode.

The compensation circuit CC may be provided within the sub-pixel SP in order to compensate for a threshold voltage of the driving transistor DR. The compensation circuit CC may be composed of one or more transistors. The compensation circuit CC may include one or more transistors and capacitors, and may be configured in various ways depending on a compensation method. The pixel including the compensation circuit CC may have various structures such as 3T1C, 4T2C, 5T2C, 6T1C, 6T2C, 7T1C, 7T2C, etc.

As shown in FIG. 1, the non-active area NA may be formed in an edge area surrounding the active area AA that displays an image. The non-active area NA includes the driving circuit area 109 for driving the plurality of sub-pixels SP, and at least one driving chip 107 may be disposed in the driving circuit area 109. The driving chip 107 may be in the form of a driving integrated circuit (D-IC). The driving chip 107 may be mounted in the non-active area NA of the display panel 110 using a chip-on-panel (COP) method. The driving chip 107 may function as a data driving circuit.

The driving circuit area 109 may further include a gate driving circuit (not shown) disposed in the non-active area NA in the form of a gate-in-panel (GIP).

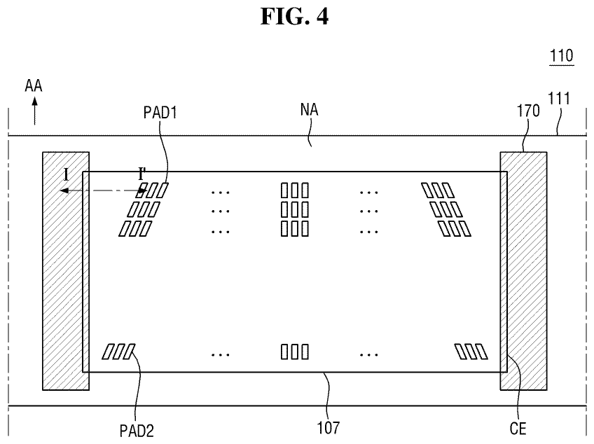

FIG. 3 is an enlarged fragmentary plan view of a part “A” of FIG. 1. FIG. 4 is a partial plan view of the driving circuit area according to the embodiment in the plan view of FIG. 1.

Referring to FIGS. 3 and 4, the display panel 110 may further include a first pad PAD1 and a second pad PAD2 which are electrically connected to the driving chip 107 disposed in the non-active area NA, and may further include a plurality of wirings W1, W2, and L1 disposed in the non-active area NA and electrically connected to the pads PAD1 and PAD2.

The driving chip 107 may be disposed in the non-active area NA of the display panel 110 using a chip on panel (COP) method. The COP method is to directly attach a drive IC onto the pads of a substrate through use of an anisotropic conductive film (ACF, see FIG. 6).

The driving chip 107 receives a signal required for driving the display panel 110 from the outside and provides or transmits the signal to the display panel 110. The driving chip 107 may be a source driver integrated circuit that provides a data signal to the data line DL of the active area AA. However, the driving chip 107 is not limited to this.

The driving chip 107 is electrically connected to the display panel 110 through the second pad PAD2 and the first pad PAD1. The driving chip 107 receives signals from the outside through the second wiring W2 and the second pad PAD2. The driving chip 107 may provide the signals received from the outside to the active area AA through the first pad PAD1, the first wiring W1, and the link lines L1.

The first pad PAD1 is disposed relatively closer to the active area AA than the second pad PAD2.

The first pad PAD1 may be provided in a plurality of rows. The plurality of first pads PAD1 arranged in one row are disposed to be spaced apart from each other. The first pad PAD1 is exemplarily shown as being arranged in three rows, but is not limited thereto and may be provided in two or less rows or in four or more rows. The first pad PAD1 may have a short side and a long side. The short side of the first pad PAD1 may be perpendicular to the long side of the driving chip 107.

The first pad PAD1 is connected to the link lines L1 and the first wirings W1. The plurality of first pads PAD1 may be connected one-to-one to the link lines L1 and the first wirings W1. The link lines L1 may be connected to the data lines DL of the active area AA.

The first pad PAD1 may be disposed on the same layer as that in which one of the plurality of adjacent wirings, for example, the first wiring W1, a third wiring W3, the link lines L1, and a fourth wiring W1 is disposed. The first pad PAD1 is made of the same material as that of one of the plurality of adjacent wirings, for example, the first wiring W1, the third wiring W3, the link lines L1, and the fourth wiring W1.

The first pad PAD1 may be disposed on the same layer as that in which the second wiring W2 that is electrically connected to the second pad PAD2 located on the opposite side of the first pad is disposed. The first pad PAD1 may be made of the same material as that of the second wiring W2.

The first pad PAD1 is connected to the driving chip 107 through an anisotropic conductive film 103 (see FIG. 6). Here, a bump 105 (see FIG. 6) disposed on the driving chip 107 and the first pad PAD1 are electrically connected. The first pads PAD1 may be connected one-to-one to the bumps 105. Accordingly, the first pad PAD1 may receive the voltage and signals applied to the driving chip 107 through the bumps 105.

The second pad PAD2 may be provided in a single row. A plurality of the second pads PAD2 arranged in one row are disposed to be spaced apart from each other. The second pad PAD2 is exemplarily shown as being arranged in one row, but is not limited thereto and may be provided in two or more rows. The second pad PAD2 may have a short side and a long side. The short side of the second pad PAD2 may be perpendicular to the long side of the driving chip 107.

The second pad PAD2 is connected to the second wirings W2. The plurality of second pads PAD2 may be connected one-to-one to the second wirings W2. Each of the second wirings W2 may be connected to an external circuit board (not shown).

The second pad PAD2 may be disposed on the same layer as that in which the second wiring W2 electrically connected to second pad PAD2 is disposed. The second pad PAD2 may be made of the same material as that of the second wiring W2. The second pad PAD2 may be disposed on the same layer as that in which one of the plurality of wirings adjacent to the first pad PAD1 located on the opposite side of the second pad, for example, the first wiring W1, the third wiring W3, the link lines L1, and the fourth wiring W1 is disposed. The second pad PAD2 may be made of the same material as that of one of the first wiring W1, the third wiring W3, the link lines L1, and the fourth wiring W1.

The second pad PAD2 is connected to the driving chip 107 through the anisotropic conductive film 103 (see FIG. 6). Here, the bump 105 (see FIG. 6) disposed on the driving chip 107 and the second pad PAD2 are electrically connected. The second pad PAD2 may be connected one-to-one to the bumps 105. Accordingly, the second pad PAD2 may provide an external voltage and signals to the driving chip 107 through the bumps 105.

The structures of the first pad PAD1 and the second pad PAD2 may be substantially the same.

The first wiring W1 may connect the first pad PAD1 and some of signal lines (e.g., gate line GL). The first wiring W1 may be a gate control line.

The link line L1 may connect the first pad PAD1 and some of the signal lines (e.g., data line DL).

The first wiring W1 and the link line L1 may be arranged on the same layer. The first wiring W1 and the link line L1 may be made of the same material.

The first wiring W1 and the link line L1 may be arranged in a direction intersecting the long side of the driving chip 107.

The second wiring W2 is disposed at one side end of the display panel 110 and connects the second pad PAD2 and an external circuit board (not shown). For example, the external circuit board may be a flexible circuit board (FPC). The second wiring W2 may be arranged in a direction intersecting the long side of the driving chip 107.

The second wiring W2 and the link line L1 may be arranged on the same layer. The second wiring W2 and the link line L1 may be made of the same material.

The display panel 110 may further include the third wiring W3 and the fourth wiring WP4 disposed in the non-active area NA around the driving chip 107.

The third wiring W3 may be spaced apart from the driving chip 107 without being electrically connected to the driving chip 107 and may be arranged in a direction parallel to the short side of the driving chip 107. The third wiring W3 may be power wiring.

The third wiring W3 may be disposed on the same layer as that in which the first wiring W1 is disposed. The third wiring W3 and the first wiring W1 may be made of the same material. The third wiring W3 may be disposed on the same layer as that in which the link line L1 is disposed. The third wiring W3 and the link line L1 may be made of the same material.

The third wiring W3 may be disposed on the same layer as that in which the second wiring W2 is disposed. The third wiring W3 and the second wiring W2 may be made of the same material. The third wiring W3 may be disposed on the same layer as that in which the fourth wiring W4 is disposed. The third wiring W3 and the fourth wiring W4 may be made of the same material.

The fourth wiring W4 may be arranged in a direction intersecting the short side of the driving chip 107. The fourth wiring W4 may be a multiplexer driving line or test lines.

The fourth wiring W4 may be disposed on the same layer as that in which the first wiring W1 is disposed. The fourth wiring W4 and the first wiring W1 may be made of the same material. The fourth wiring W4 may be disposed on the same layer as that in which the link line L1 is disposed. The fourth wiring W4 and the link line L1 may be made of the same material.

The fourth wiring W4 may be disposed on the same layer as that in which the second wiring W2 is disposed. The fourth wiring W4 and the second wiring W2 may be made of the same material. The fourth wiring W4 may be disposed on the same layer as that in which the third wiring W3 is disposed. The fourth wiring W4 and the third wiring W3 may be made of the same material.

The fourth wiring W4 may be disposed to overlap the crack prevention pattern 170 that is disposed to overlap the short side of the driving chip 107 at least partially.

The crack prevention pattern 170 may be arranged in the non-active area NA of the display panel 110 such that at least a portion of the crack prevention pattern 170 overlaps, as shown in FIG. 4, an edge CE of one short side of the driving chip 107.

The crack prevention pattern 170 may be arranged in the non-active area NA of the display panel 110 in a direction parallel to the edge CE of one short side of the driving chip 107. The crack prevention pattern 170 may be arranged on both short sides of the driving chip 107 to be parallel to the short side of the driving chip 107 such that at least a portion of the crack prevention pattern 170 overlaps the edges CE of both short sides of the driving chip 107.

The crack prevention pattern 170 may have a length greater than the length of the edge CE of the short side of the driving chip 107. Specifically, at least a portion of the crack prevention pattern 170 may be arranged to overlap the edge of the driving chip 107. The crack prevention pattern 170 may be arranged to overlap four points of the edge of the driving chip 107.

The crack prevention pattern 170 is arranged to overlap four points of the edge of the driving chip 107, so that it is possible to reduce the occurrence of interference caused by the driving chip 107 in the edge area of the driving chip where the interference from the driving chip 107 is relatively easy to occur.

The crack prevention pattern 170 may be disposed to be spaced apart from the first pad PAD1 and the second pad PAD2 so as not to overlap the first pad PAD1 and the second pad PAD2.

Specifically, the crack prevention pattern 170 may be arranged to be spaced apart from the first pad PAD1 so as not to overlap the first pad PAD1 that is disposed toward the active area AA in the non-active area NA and overlaps one long side of the driving chip 107. The crack prevention pattern 170 may be arranged to be spaced apart from the second pad PAD2 so as not to overlap the second pad PAD2 that is disposed in an opposite direction to the active area AA while facing the first pad PAD1 and overlaps the other long side of the driving chip 107.

The crack prevention pattern 170 may be formed in an embossed pattern based on the top surface of the substrate 111 of the display panel 110.

As described above, in the driving chip 107, the COP method attaches the source drive IC to the substrate 111. Therefore, an indentation test, etc., is performed to check the connection status of the driving chip 107, and in order to prevent or at least reduce bad connection of the driving chip 107, high pressure must be applied when bonding the driving chip 107 to the substrate 111. Relatively less wirings are arranged in the non-active area NA, such as the short side of the driving chip 107, so that stress due to pressure, etc., is easily concentrated when mounting the driving chip. Therefore, the crack prevention pattern 170 according to the embodiment of the present disclosure is arranged to overlap the edge CE of the short side of the driving chip 107 where stress is easily generated. Accordingly, it is possible to prevent or at least reduce deformation of the display panel 110 due to the stress when the driving chip 107 is mounted or to prevent or at least reduce the occurrence of crack in the display panel 110 due to the interference with the driving chip 107.

The crack prevention pattern 170 of the embodiment of the present disclosure is arranged to overlap the edge CE of the short side of the driving chip 107, thereby preventing cracks around the driving chip 107 when the driving chip 107 is bonded. As a result, it is possible to prevent or at least reduce moisture penetration due to the crack, the lifting of surrounding insulating layers, for example, a gate insulating layer 123 or an interlayer insulating layer 125 shown in FIG. 6, due to the moisture penetration, and the occurrence of crack in the surrounding insulating layers due to the lifting.

Since the crack prevention pattern 170 according to the embodiment of the present disclosure can prevent or at least reduce cracks from occurring in the insulating layers disposed around the driving chip 107, it is possible to prevent or at least reduce that surrounding pads PAD1 and PAD2 or the plurality of wirings W1, W2, W3, W4, and L1 are corroded or cracked through the moisture penetration due to the cracks of the insulating layer.

The crack prevention pattern 170 according to the embodiment of the present disclosure can prevent or at least reduce cracks and moisture penetration, thereby reducing the deformation of the display panel 110.

The crack prevention pattern 170 may be formed in a pattern including a metal layer.

When a metal layer is disposed as the crack prevention pattern 170, rigidity can be obtained, so that the crack prevention pattern can support against pressure-like pressing when mounting the driving chip 107, thereby preventing cracks from occurring around the driving chip 107. Therefore, the deformation of the display panel 110 can be reduced with a more improved effect.

The metal layer may be made of a material that forms the source/drain electrode or gate electrode constituting the driving transistor or switching transistor disposed in the active area AA of the display panel 110. The crack prevention pattern 170 may include the same material as that of the source/drain electrode or gate electrode constituting the switching transistor of the active area AA.

In this way, when the crack prevention pattern 170 is disposed using the same material as that of the electrode disposed in the active area AA and the same process as that of the electrode material disposed in the active area AA, production energy for producing the display device can be reduced by reducing the process steps.

The crack prevention pattern 170 may be made of the same material as that of the first pad PAD1 disposed in the non-active area NA and electrically connected to the driving chip 107. The crack prevention pattern 170 may be disposed on the same layer as that in which the first pad PAD1 is disposed. The crack prevention pattern 170 may be made of the same material as that of the second pad PAD2 disposed in the non-active area NA and electrically connected to the driving chip 107. The crack prevention pattern 170 may be disposed on the same layer as that in which the second pad PAD2 is disposed.

In this way, when the crack prevention pattern 170 is disposed using the same material as that of the first pad PAD1 or the second pad PAD2 disposed in the non-active area NA and the same process as that of the first pad PAD1 material or the second pad PAD2 material disposed in the non-active area NA, the production energy for producing the display device can be reduced by reducing the process steps.

The crack prevention pattern 170 may be disposed on the same layer as that in which one of the plurality of wirings W1, W2, W3, W4, and L1 disposed in the non-active area NA is disposed and may be made of the same material as that of one of the plurality of wirings W1, W2, W3, W4, and L1.

As described above, when the crack prevention pattern 170 is disposed in the same process using an electrode material forming process, a pad forming process, or a wiring forming process disposed on the display device, a manufacturing process for producing the display device can be reduced. Accordingly, the generation of greenhouse gas by the manufacturing process can be reduced, so that environment/social/governance (ESG) can be implemented.

As shown in FIG. 3, the crack prevention pattern 170 is arranged not to overlap one of the plurality of wirings W1, W2, W3, W4, and L1 arranged adjacent to each other in the non-active area NA.

The crack prevention pattern 170 may overlap one of the plurality of wirings W1, W2, W3, W4, and L1 disposed adjacent to each other in the non-active area NA. For example, when the crack prevention pattern 170 overlaps the fourth wiring W4 disposed to overlap one short side of the driving chip 107, the crack prevention pattern 170 and the fourth wiring W4 may be disposed in different layers. Here, the crack prevention pattern 170 may be made of a material different from that of the fourth wiring W4.

The crack prevention pattern 170 includes a metal layer, but is floating so that voltages and signals are not applied.

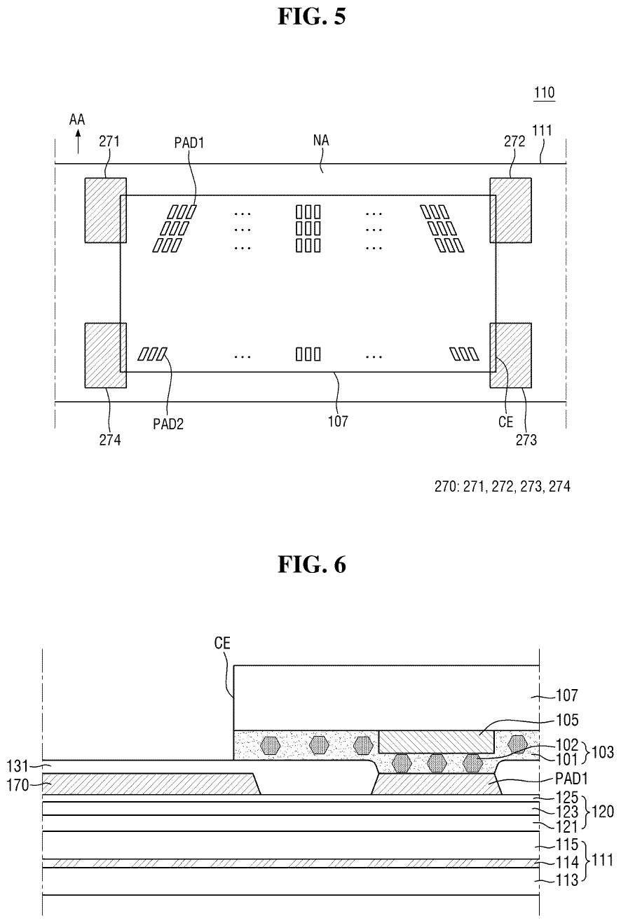

FIG. 5 is a partial plan view of a driving circuit area according to another embodiment in the plan view of FIG. 1. The components having the same reference numerals as those described with reference to FIGS. 1 to 4 can be applied or implemented in the same manner as the embodiments described with reference to FIGS. 1 to 4, or can be applied or implemented by embodiments in combination or combined with the embodiments described with reference to FIGS. 1 to 4. The description of the components having the same reference numerals will be omitted.

Referring to FIG. 5, a crack prevention pattern 270 may be arranged such that, in the non-active area NA of the display panel 110, at least a portion thereof overlaps the edges CE of both short sides of the driving chip 107 and at least a portion does not overlap.

A plurality of the crack prevention patterns 270 may be arranged to be spaced apart from each other so as to overlap four points of the edge of the driving chip 107.

The crack prevention pattern 270 may include a first crack prevention pattern 271, a second crack prevention pattern 272, a third crack prevention pattern 273, and a fourth crack prevention pattern 274. The first to fourth crack prevention patterns 271 to 274 may be arranged to overlap the four points of the edge of the driving chip 107, respectively.

Specifically, the first crack prevention pattern 271 may be disposed in the non-active area NA of the display panel 110 in a direction parallel to the edge CE of one short side of the driving chip 107 such that at least a portion of the first crack prevention pattern 271 overlaps the edge CE of one short side of the driving chip 107 and at least a portion of the first crack prevention pattern 271 does not overlap. The first crack prevention pattern 271 may be disposed such that at least a portion of the first crack prevention pattern 271 overlaps one long side of the driving chip 107.

The first crack prevention pattern 271 may be disposed adjacent to the first pad PAD1 and spaced apart from the first pad PAD1 so as not to overlap the first pad PAD1.

The first crack prevention pattern 271 may have a length smaller than the length of the edge CE of the short side of the driving chip 107. The first crack prevention pattern 271 may be arranged in an embossed pattern.

The second crack prevention pattern 272 may be disposed in the non-active area NA of the display panel 110 in a direction parallel to the edge CE of the other short side of the driving chip 107 such that at least a portion of the second crack prevention pattern 272 overlaps the edge CE of the other short side of the driving chip 107 and at least a portion of the second crack prevention pattern 272 does not overlap. The second crack prevention pattern 272 may be arranged to be spaced apart from the first crack prevention pattern 271 and overlap the edge CE of the other short side of the driving chip 107. The second crack prevention pattern 272 may be arranged such that at least a portion of the second crack prevention pattern 272 overlaps one long side of the driving chip 107.

The second crack prevention pattern 272 may be disposed adjacent to the first pad PAD1 and spaced apart from the first pad PAD1 so as not to overlap the first pad PAD1.

The second crack prevention pattern 272 may have a length smaller than the length of the edge CE of the short side of the driving chip 107. The second crack prevention pattern 272 may be arranged in an embossed pattern.

The third crack prevention pattern 273 may be disposed in the non-active area NA of the display panel 110 in a direction parallel to the edge CE of the other short side of the driving chip 107 such that at least a portion of the third crack prevention pattern 273 overlaps the edge CE of the other short side of the driving chip 107 and at least a portion of the third crack prevention pattern 273 does not overlap. The third crack prevention pattern 273 may be arranged to be spaced apart from the second crack prevention pattern 272 and overlap the edge CE of the other short side of the driving chip 107. The third crack prevention pattern 273 may be arranged such that at least a portion of the third crack prevention pattern 273 overlaps the other long side of the driving chip 107.

The third crack prevention pattern 273 may be disposed adjacent to the second pad PAD2 and spaced apart from the second pad PAD2 so as not to overlap the second pad PAD2.

The third crack prevention pattern 273 may have a length smaller than the length of the edge CE of the short side of the driving chip 107. The third crack prevention pattern 273 may be arranged in an embossed pattern.

The fourth crack prevention pattern 274 may be disposed in the non-active area NA of the display panel 110 in a direction parallel to the edge CE of one short side of the driving chip 107 such that at least a portion of the fourth crack prevention pattern 274 overlaps the edge CE of one short side of the driving chip 107 and at least a portion of the fourth crack prevention pattern 274 does not overlap. The fourth crack prevention pattern 274 may be disposed such that at least a portion of the fourth crack prevention pattern 274 overlaps one long side of the driving chip 107.

The fourth crack prevention pattern 274 may be disposed adjacent to the second pad PAD2 and spaced apart from the second pad PAD2 so as not to overlap the second pad PAD2.

The fourth crack prevention pattern 274 may have a length smaller than the length of the edge CE of the short side of the driving chip 107. The fourth crack prevention pattern 274 may be arranged in an embossed pattern.

The crack prevention pattern 270 is arranged to overlap four points of the edge of the driving chip 107, so that it is possible to reduce the occurrence of interference caused by the driving chip 107 in the edge area of the driving chip where the interference from the driving chip 107 is relatively easy to occur.

When the first crack prevention pattern 271 and the fourth crack prevention pattern 274 are arranged to be spaced apart from each other in such a manner as to overlap the edge of one short side of the driving chip 107, it is possible to prevent or at least reduce that a step difference occurs due to overlap with the wiring disposed adjacent to one short side of the driving chip 107.

When the second crack prevention pattern 272 and the third crack prevention pattern 273 are arranged to be spaced apart from each other in such a manner as to overlap the edge of one short side of the driving chip 107, it is possible to prevent or at least reduce that a step difference occurs due to overlap with the wiring disposed adjacent to the other short side of the driving chip 107.

Relatively fewer wirings are arranged in the non-active area NA, such as the short side of the driving chip 107, so that stress due to pressure, etc., is easily concentrated when mounting the driving chip. Therefore, at least a portion of the crack prevention pattern 270 according to the embodiment of the present disclosure is arranged to overlap the four points of the edge and the edge CE of the short side of the driving chip 107 where stress is easily generated. Accordingly, it is possible to prevent or at least reduce deformation of the display panel 110 due to the stress when the driving chip 107 is mounted or to prevent or at least reduce the occurrence of crack in the display panel 110 due to the interference with the driving chip 107.

The crack prevention pattern 270 of the embodiment of the present disclosure is arranged to overlap the four points of the edge and the edge CE of the short side of the driving chip 107, thereby preventing cracks around the driving chip 107 when the driving chip 107 is bonded. As a result, it is possible to prevent or at least reduce moisture penetration due to the crack, the lifting of surrounding insulating layers due to the moisture penetration, and the occurrence of crack in the surrounding insulating layers due to the lifting.

Since the crack prevention pattern 270 according to the embodiment of the present disclosure can prevent or at least reduce cracks from occurring in the insulating layers disposed around the driving chip 107, it is possible to prevent or at least reduce that surrounding pads PAD1 and PAD2 or the surrounding wirings are corroded or cracked through the moisture penetration due to the cracks of the insulating layer.

The first to fourth crack prevention patterns 271 to 274 may be formed of a pattern including a metal layer.

When a metal layer is disposed as the crack prevention pattern 270, rigidity can be obtained, so that the crack prevention pattern can support against pressure-like pressing when mounting the driving chip 107, thereby preventing cracks from occurring around the driving chip 107. Therefore, the deformation of the display panel 110 can be reduced with a more improved effect.

The metal layer constituting the crack prevention pattern 270 may include the same material as that of the electrode constituting the driving transistor or switching transistor disposed in the active area AA of the display panel 110.

The metal layer constituting the crack prevention pattern 270 may be disposed on the same layer as that in which the first pad PAD1 or the second pad PAD2 is disposed. The metal layer may include the same material as that of the first pad PAD1 or the second pad PAD2. The crack prevention pattern 270 may be disposed on the same layer as that in which one of the plurality of wirings disposed in the non-active area NA is disposed and may be made of the same material as that of one of the plurality of wirings.

In this way, when the crack prevention pattern 270 is disposed using the same material as that of one of the electrode disposed in the active area AA, the first pad PAD1, the second pad PAD2, and the adjacent wiring disposed in the non-active area NA and the same process as that of the material of one of the electrode disposed in the active area AA, the first pad PAD1, the second pad PAD2, and the adjacent wiring disposed in the non-active area NA, the production energy for producing the display device can be reduced by reducing the process steps.

The features of the various embodiments of the present disclosure can be partially or entirely coupled to or combined with each other, and the features can be technically and variously connected and driven. Also, the embodiments can be implemented independently of each other or together in an association relationship.

Hereinafter, an example of the stacked structure of the crack prevention pattern 170 described above will be described with reference to FIG. 6.

The display panel 110 includes the substrate 111. An insulating layer 120 may be disposed in the non-active area NA on the substrate 111. The crack prevention pattern 170 may be disposed on the insulating layer 120 such that at least a portion of the crack prevention pattern 170 overlaps the edge CE of one short side of the driving chip 107. A planarization layer 131 may be disposed on the insulating layer 120 in such a manner as to cover at least a portion of the crack prevention pattern 170.

A plurality of the insulating layers 120 may be stacked and disposed in the non-active area NA on the substrate 111. The insulating layer 120 may include a buffer layer 121, the gate insulating layer 123, and the interlayer insulating layer 125.

The substrate 111 is made of a flexible plastic material and may have flexible properties. The substrate 111 may be formed to include polyimide and may include a flexible and thin glass material.

The substrate 111 may include a support substrate such as polyethylene terephthalate (PET), a polyimide film, and an adhesive film for adhering PET and polyimide film, such as pressure sensitive adhesive (PSA).

The substrate 111 may include a first substrate 113, a second substrate 115, and an intermediate layer 114 disposed between the first substrate 113 and the second substrate 115. The intermediate layer 114 may include an adhesive material. The intermediate layer 114 may include an insulating material such as silicon nitride or silicon oxide.

On the substrate 111, the plurality of sub-pixels SP may be, as shown in FIG. 1, disposed in the active area AA, and the driving chip 107 may be disposed in the non-active area NA.

The buffer layer 121 is disposed on the substrate 111. The buffer layer 121 is disposed on the substrate 111 to protect thin film transistors and light emitting devices disposed in the active area AA from moisture penetrating through the substrate 111. The buffer layer 121 is arranged to overlap the driving chip 107 in the non-active area AA and prevents or at least reduces moisture from penetrating from the edge of the substrate 111. The buffer layer 121 may be arranged to overlap the crack prevention pattern 170.

The buffer layer 121 may be composed of a plurality of inorganic layers alternately stacked. For example, the buffer layer 121 may include a multilayer formed by alternately stacking one or more inorganic layers selected from the group comprising a silicon oxide layer (SiOx), a silicon nitride layer (SiNx), and a silicon oxynitride layer (SiOxNy).

The gate insulating layer 123 is disposed on the buffer layer 121. The gate insulating layer 123 is disposed in the active area AA shown in FIGS. 1 and 2 to prevent or at least reduce a short-circuit between electrodes constituting the thin film transistors. The gate insulating layer 123 is disposed to extend to the non-active area NA and can prevent or at least reduce a short-circuit between the electrodes constituting the thin film transistors disposed in the non-active area NA. The gate insulating layer 123 may be arranged to overlap the driving chip 107 in the non-active area NA. The gate insulating layer 123 may be arranged to overlap the crack prevention pattern 170.

The gate insulating layer 123 may include an inorganic layer, for example, a silicon oxide layer (SiOx), a silicon nitride layer (SiNx), or a multilayer thereof.

The interlayer insulating layer 125 may be disposed on the gate insulating layer 123. The interlayer insulating layer 125 is disposed in the active area AA shown in FIGS. 1 and 2 and functions to electrically insulate electrodes that constitute the thin film transistors and are arranged above and below. The interlayer insulating layer 125 may extend to the non-active area NA and electrically insulate the electrodes that constitute the thin film transistors disposed in the non-active area NA and are disposed above and below. The interlayer insulating layer 125 may be arranged to overlap the driving chip 107 in the non-active area NA. The interlayer insulating layer 125 may be arranged to overlap the crack prevention pattern 170.

The interlayer insulating layer 125 may include an inorganic material. The inorganic material may include, for example, silicon nitride, silicon oxynitride, silicon oxide, etc. Alternatively, the interlayer insulating layer 125 may be disposed including a multilayer thereof.

The crack prevention pattern 170 is arranged on the plurality of insulating layers 120 (for example, on the uppermost insulating layer of the plurality of insulating layers included in the insulating layer 120). The crack prevention pattern 170 may be arranged in an embossed pattern on the top surface of the insulating layer 120. A pad, for example, the first pad PAD1, may be arranged on the insulating layer 120 and be spaced apart from the crack prevention pattern 170.

The crack prevention pattern 170 may include a metal layer.

When a metal layer is disposed as the crack prevention pattern 170, rigidity can be obtained, so that the crack prevention pattern can support against pressure-like pressing when mounting the driving chip 107, thereby preventing cracks from occurring around the driving chip 107. Therefore, the deformation of the display panel 110 can be reduced with a more improved effect.

The crack prevention pattern 170 may be disposed on the same layer as that in which the first pad PAD1 is disposed. The crack prevention pattern 170 may include the same material as that of the first pad PAD1. When the crack prevention pattern 170 is disposed using the same material as that of the first pad PAD1 disposed in the non-active area NA and the same process as that of the first pad PAD1 material disposed in the non-active area NA, the production energy for producing the display device can be reduced by reducing the process steps.

The planarization layer 131 is disposed on the crack prevention pattern 170. The planarization layer 131 may cover the embossed crack prevention pattern 170 to provide a flat surface. The planarization layer 131 may be disposed to extend to the side of the first pad PAD1 in such a manner as to cover the side of the first pad PAD1 and the insulating layer 120 exposed to a spaced space between the crack prevention pattern 170 and the first pad PAD1.

The planarization layer 131 may be disposed to overlap the edge CE of one short side of the driving chip 107. Here, the edge CE of one short side of the driving chip 107 may overlap the planarization layer 131 and the crack prevention pattern 170.

The planarization layer 131 may include an organic material. The organic material may include at least one of acryl resin, epoxy resin, phenolic resin, polyamide resin, and polyimide resin.

In addition to the insulating layer 120 described above, various organic or inorganic layers may be further disposed between the substrate 111 and the planarization layer 131.

The driving chip 107 may include the bump 105 corresponding to the first pad PAD1. A plurality of the bumps 105 may be arranged to face the pads disposed in the non-active area NA, such as the first pad PAD1. The bump 105 may be arranged to be spaced apart from the crack prevention pattern 170.

The anisotropic conductive film 103 is disposed between the driving chip 107 and the pads PAD1 and PAD2.

The anisotropic conductive film 103 includes an adhesive member 101 and a plurality of conductive balls 102. The adhesive member 101 allows the driving chip 107 to be attached to the display panel 110, and the conductive balls 102 are irregularly distributed within the adhesive member 101 to cause the driving chip 107 to be electrically connected to the first pad PAD1.

The conductive ball 102 may be formed by using conductive particles themselves, by using polymer resin particles coated with a metal layer or by using particles obtained by coating an insulating resin on the surface of the conductive particles or metal layer-coated particles. For example, the metal layer may be made of a material such as nickel (Ni) or gold (Au).

The anisotropic conductive film 103 may be disposed to overlap an edge portion of the planarization layer 131 that overlaps the edge CE of the driving chip 107. The planarization layer 131 is arranged to overlap the side of the crack prevention pattern 170 and the edge of the driving chip 107 so that the crack prevention pattern 170 is prevented from being electrically connected to the conductive ball 102 of the anisotropic conductive film 103.

Since the driving chip 107 is electrically connected to the first pad PAD1 through the conductive ball 102, pressure is applied to mount the driving chip 107 to cause the conductive ball 102 to contact with the bump 105 and the first pad PAD1. The crack prevention pattern 170 according to embodiment of the present disclosure is arranged such that at least a portion of the crack prevention pattern 170 overlaps the edge of the short side of the driving chip 107, so that it is possible to prevent or at least reduce that stress due to pressure, etc., is concentrated when mounting the driving chip 107 and the stress is generated. Therefore, it is possible to prevent or at least reduce deformation of the display panel 110 due to the stress or to prevent or at least reduce the occurrence of crack in the display panel 110 due to the interference with the driving chip 107.

The crack prevention pattern 170 of the embodiment of the present disclosure is arranged to overlap the edge CE of the short side of the driving chip 107, thereby preventing cracks around the driving chip 107 when the driving chip 107 is bonded (e.g., insulating layer 120 or one or more layers of insulating layer 120). As a result, it is possible to prevent or at least reduce moisture penetration due to the crack, the lifting of surrounding insulating layers 120 due to the moisture penetration, and the occurrence of crack in the surrounding insulating layers (e.g., insulating layer 120 or one or more layers of insulating layer 120) due to the lifting.

Since the crack prevention pattern 170 according to the embodiment of the present disclosure can prevent or at least reduce cracks from occurring in the insulating layers 120 disposed around the driving chip 107, it is possible to prevent or at least reduce that the first surrounding pad PAD1, etc., are corroded or cracked through the moisture penetration due to the cracks of the insulating layer 120.

The crack prevention pattern 170 according to the present disclosure can prevent or at least reduce cracks and moisture penetration, thereby reducing the deformation of the display panel 110.

In the display device 100 according to the present disclosure, the crack prevention pattern 170 is arranged such that at least a portion of the crack prevention pattern 170 overlaps the edge of the driving chip 107, thereby blocking moisture penetration and preventing the corrosion of the metal disposed in the non-active area NA of the display device 100. As a result, the reliability of the display device 100 can be improved.

According to the display device according to the embodiment, the defect occurrence of the display device 100 is minimized. Accordingly, the production energy for producing the display device can be reduced and the use of hazardous production materials or regulated materials can be reduced, so that the display device is advantageous for recycling and leads to the implementation of the eco-friendly display device 100.

In the embodiment shown in FIG. 6, the crack prevention pattern 170 is shown and described as being disposed on the same layer and made of the same material as the first pad PAD1. However, according to the embodiment of the present disclosure, the crack prevention pattern 170 may be disposed on the same layer and made of the same material as one of adjacent wirings, for example, the first wiring W1, the second wiring W2, the third wiring W3, the fourth wiring W4, and the link line L1.

Although embodiments of the present disclosure were described above, these are just examples and do not limit the present disclosure. The present disclosure described above is not limited to the above-described embodiments and the accompanying drawings. The features, structures, effects and the like provided in each embodiment can be combined or modified. Therefore, contents related to the combination and modification should be construed to be included in the scope of the present invention.

REFERENCE NUMERALS

| | |
|---|---|
| 101: Adhesive Material | 102: Conductive Ball |
| 103: Anisotropic Conductive Film | 105: Bump |
| 107: Driving Chip | 109: Driving Circuit Area |
| 110: Display Panel | 111: Substrate |
| 113: First Substrate | 114: Intermediate Layer |
| 115: Second Substrate | 120: Insulating Layer |
| 121: Buffer Layer | 123: Gate Insulating Layer |
| 125: Interlayer Insulating Layer | 131: Planarization Layer |
| 170: Crack Prevention Pattern | |

What is claimed is:

1. A display device comprising:
a display panel including an active area and a non-active area; and
a driving chip in the non-active area,
wherein the display panel includes a crack prevention pattern, and at least a portion of the crack prevention pattern overlaps an edge of one short side of the driving chip.

2. The display device of claim 1, wherein the crack prevention pattern is in the non-active area in a direction parallel to the edge of one short side of the driving chip.

3. The display device of claim 1, wherein the crack prevention pattern is electrically floating.

4. The display device of claim 1, wherein the crack prevention pattern is on both short sides of the driving chip parallel to the short side of the driving chip such that at least a portion of the crack prevention pattern overlaps edges of both short sides of the driving chip.

5. The display device of claim 1, wherein at least a portion of the crack prevention pattern overlaps the edge of the driving chip.

6. The display device of claim 5, wherein the crack prevention pattern overlaps four points of the edge of the driving chip.

7. The display device of claim 1, wherein the display panel comprises:
a substrate;
a plurality of insulating layers stacked in the non-active area on the substrate;
a planarization layer on the crack prevention pattern on the plurality of insulating layers; and
a first pad that is spaced apart from the crack prevention pattern,
wherein the planarization layer is on the plurality of insulating layers exposed to a space between the crack prevention pattern and the first pad, and the planarization layer is on a side of the first pad.

8. The display device of claim 7, wherein the edge of one short side of the driving chip overlaps the planarization layer and the crack prevention pattern.

9. The display device of claim 7, further comprising:
an anisotropic conductive film between the driving chip and the first pad,
wherein the anisotropic conductive film overlaps at least a portion of the planarization layer and the crack prevention pattern at the edge of one short side of the driving chip.

10. The display device of claim 1, wherein the crack prevention pattern is spaced apart from a bump of the driving chip.

11. The display device of claim 1, wherein the crack prevention pattern is in an embossed pattern including a metal layer.

12. The display device of claim 1, wherein the crack prevention pattern includes a same material as that of source/drain electrodes or a gate electrode of a switching transistor in the active area.

13. The display device of claim 1, further comprising:
a first pad which is disposed toward the active area in the non-active area; and
a second pad which is disposed in an opposite direction to the active area while facing the first pad,
wherein the first pad and the second pad overlap both long sides of the driving chip, and
wherein the crack prevention pattern is spaced apart from the first pad and the second pad so as not to overlap the first pad and the second pad.

14. The display device of claim 13, wherein the crack prevention pattern includes a same material as that of the first pad or the second pad.

15. The display device of claim 1, wherein at least a portion of the crack prevention pattern does not overlap edges of both short sides of the driving chip, and the display panel comprises a plurality of crack prevention patterns spaced apart from each other to overlap four points of the edge of the driving chip.
